(19) United States
(12) Patent Application Publication
(10) Pub. No.: US 2024/0337549 A1
(43) Pub. Date: Oct. 10, 2024

(54) FLAT MESH SENSOR

(71) Applicant: BlackBox Biometrics, Inc., Rochester, NY (US)

(72) Inventors: Vincent J. Baier, Beverly, MA (US); Angela D'Orazio, Rochester, NY (US)

(21) Appl. No.: 18/294,245

(22) PCT Filed: Aug. 3, 2022
(86) PCT No.: PCT/US2022/039339

§ 371 Date: Feb. 1, 2024

Related U.S. Application Data
(60) Provisional application No. 63/229,256, filed on Aug. 4, 2021.

(51) Int. Cl. G01L 5/14; G01H 3/14; H05K 5/02; H05K 5/03

(52) U.S. Cl. CPC G01L 5/14; G01H 3/14; H05K 5/0215; H05K 5/03

(57) ABSTRACT

Systems and methods are disclosed including a blast sensor system having a blast sensor proximate an opening in an exterior surface of a housing configured to detect or monitor impulse noise or shock wave events at the exterior surface and a flat mesh sensor cover coupled to the housing having a top surface that, when coupled to the housing. extends above the exterior surface of the housing less than a radius of the opening of the housing.

### CLAIM OF PRIORITY

This application claims the benefit of priority under 35 U.S.C. § 119 (e) of U.S. Provisional Patent Application Ser. No. 63/229,256, filed on Aug. 4, 2021, which is herein incorporated by reference in its entirety.

### BACKGROUND

Unwanted or excessive sound can have deleterious effects on human health. Sounds having sound pressure levels (SPLs) above 85 decibels (dB) for extended periods of time can damage structures of the inner ear, leading to noise-induced hearing loss (NIHL). The Occupational Safety and Health Administration (OSHA) requires the employers implement hearing conservation programs when noise exposure is at or above 85 decibels averaged over 8 working hours, or an 8-hour time-weighted average (TWA). Exposure to sound events at more than 105 dB average (dBA) can cause some amount of permanent hearing loss.

Exposure to impulse events, such as blast exposure, can produce high intensity overexposures, often referred to as blast overpressure (BOP), which can pose both a risk of NIHL and a risk of traumatic brain injury (TBI) with one or more cumulative exposures. Impulse events include impulse noise events, such as gunshots, explosions, or other sound events having fast initial rise times, such as 50 us or less (e.g., frequencies of 20 kHz or higher), often with SPLs above 140 dB (depending on distance from the event).

Blast sensors can be configured to detect or monitor impulse noise or shock wave events and can be worn by a person to monitor impulse noise or shock wave event exposure of the person or attached to one or more objects (e.g., protective equipment, accessories, stationary objects, vehicles, etc.) to monitor impulse noise or shock wave event exposure to people or associated with or near the one or more objects.

Blast sensors configured to detect impulse noise or shock wave events often include one or more pressure, acoustic, or other sensors open to or facing the external environment, including, at times, in challenging conditions such as direct contact with equipment, debris, dirt, water, mud, sand, etc. Exposure to the external environment can impact sensor performance or damage the one or more blast sensors.

### SUMMARY

Systems and methods are disclosed including a blast sensor system having a blast sensor proximate an opening in an exterior surface of a housing configured to detect or monitor impulse noise or shock wave events at the exterior surface and a flat mesh sensor cover coupled to the housing having a top surface that, when coupled to the housing, extends above the exterior surface of the housing less than a radius of the opening of the housing.

This summary is intended to provide an overview of subject matter of the present patent application. It is not intended to provide an exclusive or exhaustive explanation of the disclosure. The detailed description is included to provide further information about the present patent application. Other aspects of the disclosure will be apparent to persons skilled in the art upon reading and understanding the following detailed description and viewing the drawings that form a part thereof, each of which are not to be taken in a limiting sense.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates an example prior art first blast gauge with a mesh sensor dome that rises substantially above an exterior surface of the first blast gauge.

FIG. 2 illustrates an example second blast gauge with a flat mesh sensor cover at an exterior surface of the second blast gauge.

FIGS. 3A-3B illustrate example front and top views of an example third blast gauge with a mesh sensor dome.

FIGS. 4A-4B illustrate example front and top views of an example fourth blast gauge with a flat mesh sensor cover.

FIGS. 5-11 illustrate example flat mesh sensor cover configurations with respect to an exterior surface of a blast gauge housing and an opening in the blast gauge housing over a sensing element.

FIGS. 12A-12C illustrate different mesh configurations including two or three layers of mesh having one or more different material and opening diameters.

FIGS. 13-14 illustrate example dimensions of a first flat mesh sensor cover.

FIG. 15 illustrates a cross section of an example fifth blast gauge with a flat mesh sensor cover.

FIG. 16-17 illustrate example dimensions of a second flat mesh sensor cover.

FIG. 18 illustrates an example system including a dosimeter.

FIG. 19 illustrates a block diagram of an example machine upon which any one or more of the techniques (e.g., methodologies) discussed herein may perform.

### DETAILED DESCRIPTION

Blast sensors can include one or more stationary or ambulatory sensors (e.g., each including one or more pressure, acoustic, or other sensing element) configured to detect and monitor exposure to impulse noise or shock wave events. The present inventors have recognized, among other things, a flat mesh sensor cover at a surface of a blast gauge over one or more blast sensors of the blast gauge to protect the one or more blast sensors from the external environment, providing water and debris protection to the one or more blast sensors, while improving robustness of blast sensor protection and sensing performance of detection of impulse noise or shock wave events in contrast to prior art sensors.

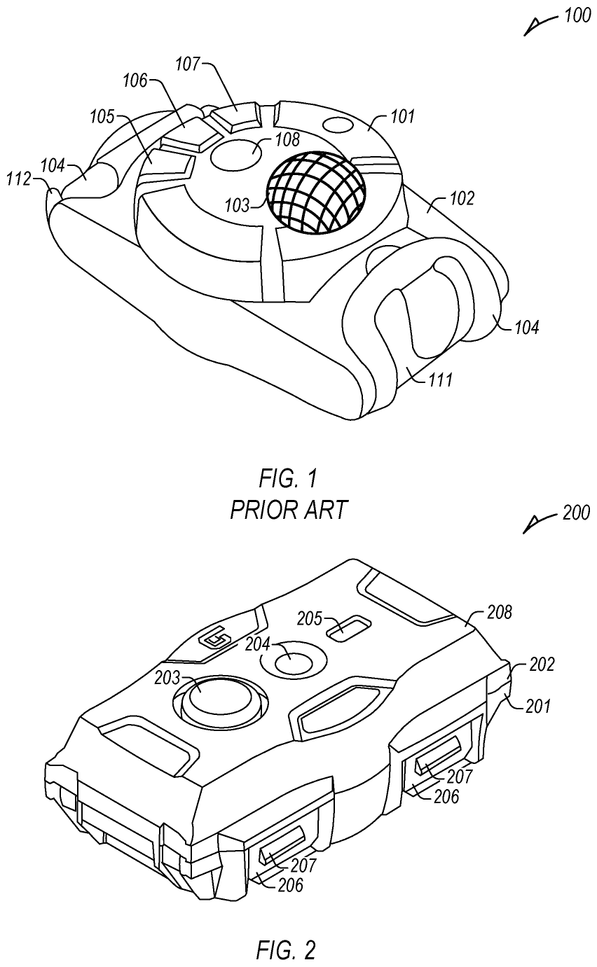

FIG. 1 illustrates an example first blast gauge 100 configured to detect impulse noise or shock wave events using a sensing element under a mesh sensor dome 103 that rises substantially above a top, exterior surface 101 of the first blast gauge 100 (e.g., greater than 5 mm, greater than 10 mm, greater than the radius of cross section of the mesh sensor dome 103 at the exterior surface 101 of the first blast gauge 100, greater than or equal to the diameter of the cross section of the mesh sensor dome 103 at the exterior surface 101 of the first blast gauge 100, etc.). The first blast gauge 100 additionally includes a button 108 and different first, second, and third indicators 105, 106, 107. An attachment cord 104 (e.g., a bungee, etc.) can attach a housing 102 of the first blast gauge 100 to one or more objects or attachment points using different mechanical grooves 111 and protrusions 112.

The mesh of the mesh sensor dome 103 is sized to allow air flow but resist water ingress. The sensing element can include a pressure sensor, such as a silicon-based piezoresistive pressure sensor, proximate an opening in the exterior surface 101 of the first blast gauge 100. The mesh sensor dome 103 can be configured to cover the opening to reduce dirt and debris collection over the sensing element and exposure of the sensing element to moisture, direct contact, etc., while still allowing airflow and detection of impulse noise or shock wave events by the sensing element.

However, under certain conditions, the protruding mesh sensor dome 103 can catch on objects that come in contact with or near the first blast gauge 100, sheer off, puncture, dent, or otherwise become damaged. Damage to the mesh sensor dome 103 can lead to exposure of the sensing element to the environment, including exposure to water, dirt, sand, mud, etc., or buildup of dirt or debris at or within the mesh sensor dome, in certain examples impacting sensor performance or rendering the first blast gauge 100 inoperable. Additionally, dirt and debris can collect within gaps or at intersections between the exterior surface 101 of the first blast gauge 100 and the vertical (or near-vertical) edge of the mesh sensor dome 103.

The present inventors have recognized, among other things, that a flat mesh sensor cover over the sensing element, in certain configurations having limited extension above the exterior surface 101 of the housing 102 of the first blast gauge 100 (e.g., less than 2 mm, 1.5 mm, 1 mm, etc.), can retain water protection of the sensing element in contrast to the mesh sensor dome 103, while improving robustness of the first blast gauge 100, reducing protruding edges of the first blast gauge 100 and the overall device profile, improving sensing performance of detection of impulse noise or shock wave events, and maintaining protection of the sensing element. In addition, eliminating gaps or steps, or increasing the angle of any intersections to be greater than 90 degrees, can reduce collection of dirt or debris, improving sensor performance in use.

FIG. 2 illustrates an example second blast gauge 200 configured to detect impulse noise or shock wave events using a sensing element under a flat mesh sensor cover 203 at an exterior surface 208 of the second blast gauge 200. In this example, the second blast gauge 200 has a split-shell configuration with separate top and bottom portions 201, 202. However, the flat mesh sensor cover 203 can similarly be used to improve performance of any number of different blast sensor housings, such as the first blast gauge 100 or other blast sensors having one or more different housings.

In contrast to the protruding mesh sensor dome of FIG. 1, the flat mesh sensor cover 203 protects the sensing element of the second blast gauge 200 without the protrusion associated with a mesh sensor dome, providing an improved, reduced overall device profile, maintaining protecting the sensing element from water, dirt, sand, mud, etc., while improving robustness of the mesh cover to rips, tears, or other damage. Importantly, in testing, the flat mesh sensor cover 203 retains the dive depth (20-foot dive depth) and pressure ratings of the mesh sensor dome illustrated in FIG. 1, while creating less turbulence at the surface of the second blast gauge 200 in contrast to the protruding mesh sensor dome of FIG. 1, improving sensor performance to impulse noise and shock wave events, and more accurately detecting peak overpressure.

The split-shell configuration of the second blast gauge 200 allows for replacement of a replaceable power source (e.g., replaceable batteries) in the open configuration without removing an attachment cord or re-securing the improved second blast gauge 200 to a previously engaged attachment surface or feature.

One or both of the top and bottom portions 201, 202 can include a groove at first and second ends configured to engage an attachment cord. The attachment cord can be placed into or removed from the grooves when the top and bottom portions 201, 202 are in an open configuration. When the top portion 202 and bottom portion 201 are in a closed configuration, the attachment cord is secured in the grooves, maintaining positive retention of the attachment cord and the improved second blast gauge 200 to any engaged attachment surface or feature while the integrity of the attachment cord remains, or until the top and bottom portions 201, 202 are transitioned to an open configuration. Even in the open configuration, the second blast gauge 200 retains the attachment features of the prior art blast gauges.

In an example, the top portion 202 is coupled to the bottom portion 201 at one side by a hinge or other mechanical mechanism configured to retain connection when open, and is configured to engage a second opposite second side using one or more mechanical engagement features, such as male and female mating joints, cantilever hook, snap fit components, etc. In other examples, the top portion 202 can be coupled to the bottom portion 201 at multiple sides using one or more mechanical features (with or without hinges or other retention features), or can be secured once coupled in a closed configuration using a clasp, latch, or other mechanical locking mechanism. In an example, the bottom portion 201 can include keepers 207 and a top portion 202 can include corresponding latches 206 configured to engage the keepers 207 to secure the bottom portion 201 to the top portion 202.

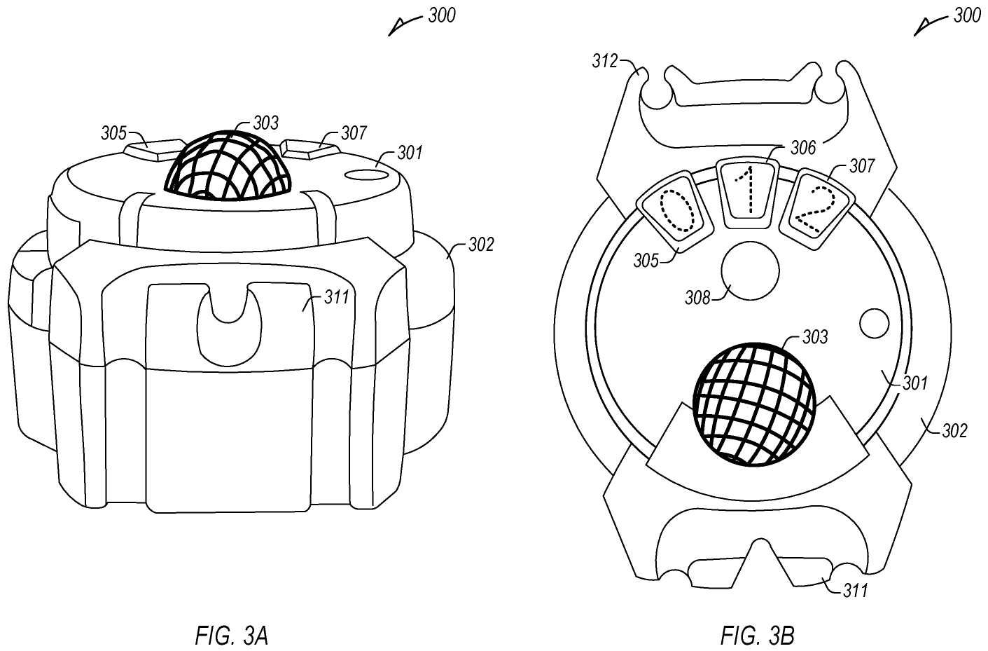

FIGS. 3A-3B illustrate front and top views of an example third blast gauge 300 with a mesh sensor dome 303 (similar to that illustrated in FIG. 1) of mesh material over a pressure sensor at a top, exterior surface 301 to reduce dirt and debris collection over the pressure sensor. The third blast gauge 300 includes a button 308, and different first, second, and third indicators 305, 306, 307. An attachment cord (e.g., a bungee, etc.) can attach a body portion 302 of the third blast gauge 300 to one or more objects or attachment points using different mechanical grooves 311 and protrusions 312.

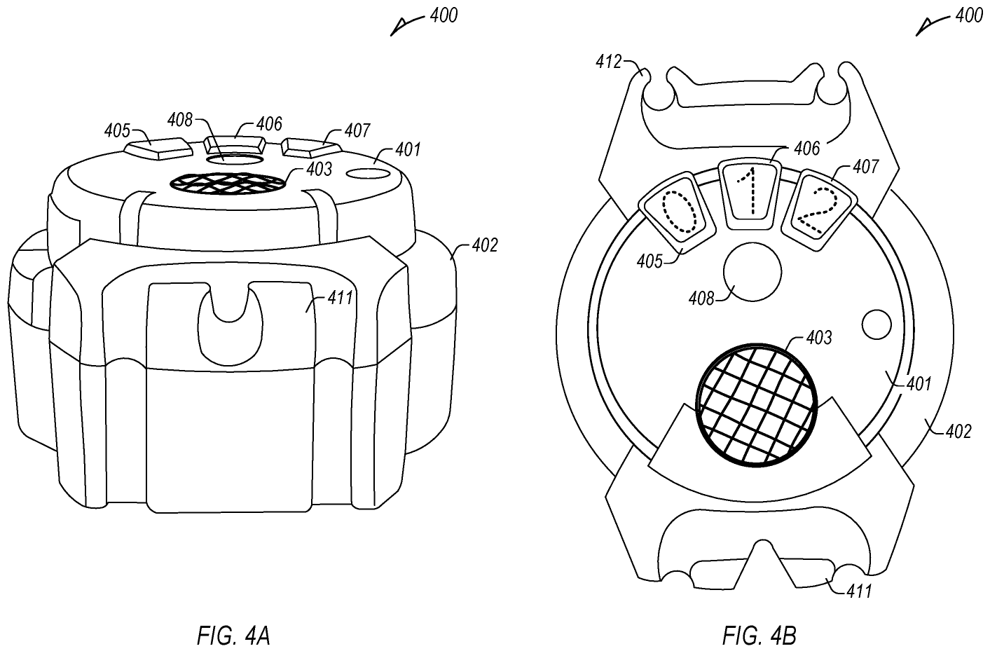

FIGS. 4A-4B illustrate front and top views of an example fourth blast gauge 400 with a flat mesh sensor cover 403 (similar to that illustrated in FIG. 2) of mesh material over a pressure sensor at an exterior surface 401. The flat mesh sensor cover 403 reduces the overall profile of the fourth blast gauge 400, reducing external protrusions from the fourth blast gauge 400 while maintaining protection of the sensing element from water, dirt, sand, mud, and other elements, and increasing robustness of the mesh sensor cover. In an example, the flat mesh sensor cover 403 can be sealed into a housing of the fourth blast gauge 400 using heat (e.g., hot air, hot melted, etc.). The thermoplastic of the housing, melted to the flat mesh sensor cover 403, can act as an adhesive and sealant. In certain examples, a top surface of the flat mesh sensor cover 403 is substantially parallel to the exterior surface 401 of the fourth blast gauge 400. In other examples, the top surface of the flat mesh sensor cover does not extend above the exterior surface 401 of the fourth blast gauge 400.

The fourth blast gauge 400 includes a button 408, and different first, second, and third indicators 405, 406, 407. An attachment cord (e.g., a bungee, etc.) can attach a body portion 402 of the fourth blast gauge 400 to one or more objects or attachment points using different mechanical grooves 411 and protrusions 412.

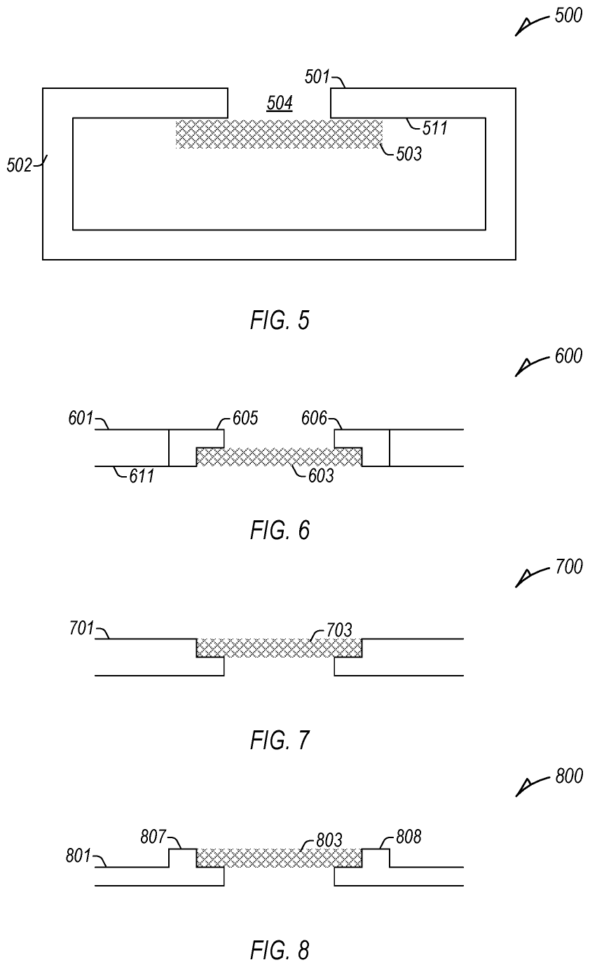

FIGS. 5-11 illustrate example cross sections of flat mesh sensor cover configurations 500-1100 with respect to an exterior surface of a blast gauge housing and an opening in the blast gauge housing over a sensing element.

FIG. 5 illustrates a cross section of a first flat mesh sensor cover configuration 500 directly attached or adhered to an interior surface 511 of the blast gauge housing 502, or conversely to an exterior surface 501 of the blast gauge housing 502 (the opposite of that illustrated in FIG. 5), covering an opening 504 in an exterior surface 501 of the blast gauge housing 502 over the sensing element (not shown). However, in both configurations, attached or adhered to the interior surface 511 or conversely to the exterior surface 501 of the blast gauge housing 502, such as with an adhesive, etc., there is potential for dirt or debris to collect at the step associated with the opening 504 of the blast gauge housing 502, or with the edge of the flat mesh sensor cover 503, filling right angles, impacting air flow through the flat mesh sensor cover 503 or creating turbulence, negatively impacting sensor performance. In addition, the exposed opening 504 in the blast gauge housing 502 and step down to the flat mesh sensor cover 503, such as with respect to the flat mesh sensor cover 503 directly attached or adhered to the interior surface 511 of the blast gauge housing 502 as illustrated in FIG. 5, can create turbulence with respect to an impulse noise or shock wave event, reducing detection accuracy of incident overpressure. The edges of the flat mesh sensor cover 503, such as with respect to the flat mesh sensor cover 503 directly attached or adhered to the exterior surface 501 of the blast gauge housing 502, can also create turbulence, reducing detection sensitivity and impacting sensor response.

FIG. 6 illustrates a cross section of a second flat mesh sensor cover configuration 600, similar to the first flat mesh sensor cover configuration 500 of FIG. 5, but with a recessed well illustrated by cross section steps 605, 606 to reduce a height of a step between the flat mesh sensor cover 603 and the interior surface 611 or exterior surface 601 of the blast gauge housing, reducing dirt and debris collection and turbulence associated with the step, improving sensor performance, but adding a manufacturing feature. The recessed well can also increase attachment or adherence of the flat mesh sensor cover 603 to the blast gauge housing by providing multiple adherence surfaces to the flat mesh sensor cover 603, such as for adhesives to attach the flat mesh sensor cover 603 to the recessed well at the surface and sidewalls of the recessed well.

In certain examples, in the configuration illustrated in FIG. 6, the edges of the opening at the exterior surface 601 of the blast gauge housing can be rounded (e.g., concave or convex), contoured, or angled to reduce the angle of intersection between a top surface of the flat mesh sensor cover 603 and the opening to reduce collection of dirt or debris.

FIG. 7 illustrates a cross section of a third flat mesh sensor cover configuration 700 with a recessed well in the exterior surface 701 of the blast gauge housing, with a top surface of the flat mesh sensor cover 703 substantially parallel to an exterior surface 701 of the blast gauge housing. In contrast to the configuration illustrated in FIG. 6, the flat mesh sensor cover 703 can provide improved aerodynamics to overpressure (e.g., reduced turbulence) and preserve internal space in the blast gauge housing, but the attachment of the flat mesh sensor cover 703 (e.g., adhesive, etc.) can be more exposed to the elements, increasing the likelihood that the flat mesh sensor cover 703 be damaged or inadvertently removed.

FIG. 8 illustrates a cross section of a fourth flat mesh sensor cover configuration 800 with raised protrusions 807, 808 on an exterior surface 801 of the blast gauge housing that the flat mesh sensor cover 803 resides within, providing multiple adherence surfaces, offering additional protection to a top surface of the flat mesh sensor cover 803, preserving internal space in the blast gauge housing, reducing chance of impact to the flat mesh sensor cover 803, instead redirecting impacts to the blast gauge housing itself, and relocating dirt and debris collection associated with any step associated with the flat mesh sensor cover 803 to outside of the opening, but adding one or more manufacturing steps to the blast gauge housing. In other examples, the outer edge of the raised protrusions 807, 808 can be rounded or angled to reduce dirt or debris collection and turbulence associated with the raised protrusions 807, 808.

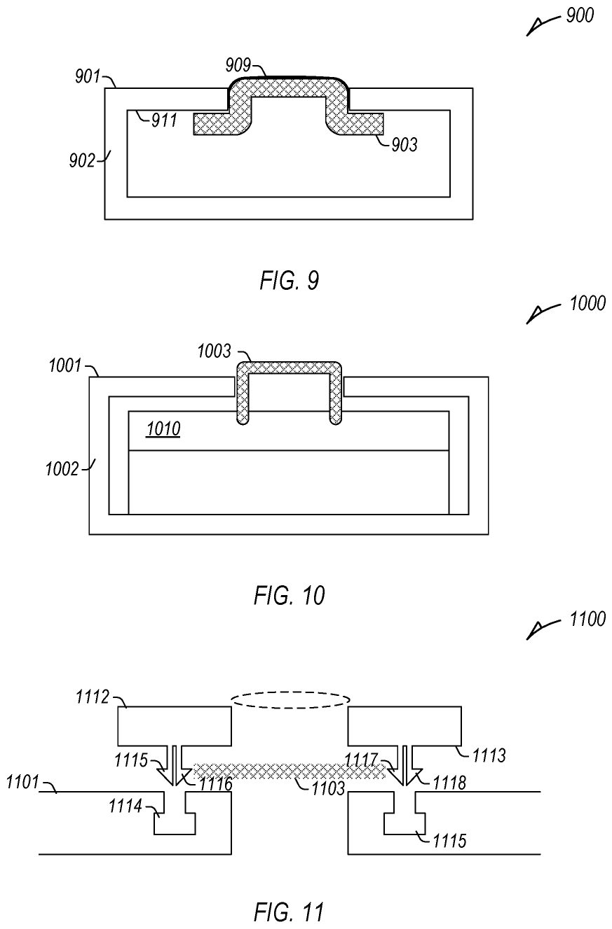

FIG. 9 illustrates a cross section of a fifth flat mesh sensor cover configuration 900, adding a physical step to the flat mesh sensor cover 903 that engages with the interior surface 911 of the blast gauge housing 902, providing multiple adherence surfaces without adding features to the blast gauge housing 902. In addition, a top surface of the flat mesh sensor cover 903 can be curved or rounded, such as from bending a metal mesh, reducing dirt or debris collection as well as turbulence associated with a gap or step in an exterior surface 901 of the blast gauge housing 902. The rounded edges of the flat mesh sensor cover 903 above the exterior surface 901 of the blast gauge housing 902 provide a compromise between aerodynamics and dirt and debris collection.

In certain examples, the fifth flat mesh sensor cover configuration 900 can be combined with a recessed well at the interior surface 911 of the blast gauge housing 902, similar to that illustrated in FIG. 6. In other examples, an additional mesh sensor cover 909, such as an additional layer of mesh having different material diameter (e.g., wire diameter, etc.) or different opening diameters than the flat mesh sensor cover 903, can be located above or below the flat mesh sensor cover 903, covering all or a portion of the opening in the blast gauge housing 902, have the same or different exterior dimensions as the flat mesh sensor cover 903. In certain examples, the flat mesh sensor covers described herein can be made of one or more layers of mesh material with different material diameters or different opening diameters to optimize for desired strength and ingress protection. In an example, the additional mesh sensor cover 909 can be adhered to the flat mesh sensor cover 903, to the sidewalls of the opening of the blast gauge housing 902, or otherwise positioned to provide water and debris protection without negatively impacting sensor performance.

FIG. 10 illustrates a cross section of a sixth flat mesh sensor cover configuration 1000 including a flat mesh sensor cover 1003 physically attached to a PC board 1010 in the blast gauge housing 1002 (e.g., solder set to the PC board 1010, etc.). The sensing element can be physically coupled to the PC board 1010, in certain examples providing electrical connection between the sensing element (not shown) and other electronic circuits of the blast gauge housing 1002. In an example, the flat mesh sensor cover 1003 can be physically attached to the PC board 1010 in place about the sensing element, ensuring placement relative to the sensing element instead of to the exterior surface 1001 of the blast gauge housing 1002. In certain examples, the flat mesh sensor cover 1003 can be physically attached to both the PC board 1010 and the blast gauge housing 1002 to ensure attachment and adherence, and to seal any gap that exists between the flat mesh sensor cover 1003 and the opening in the blast gauge housing 1002.

FIG. 11 illustrates a cross section a seventh flat mesh sensor cover configuration 1100 including a flat mesh sensor cover 1103 over an opening in the blast gauge housing secured in place by a snap-in cover illustrated by first and second components 1112, 1113, reducing the amount of adhesive required to maintain the flat mesh sensor cover 1103 to an exterior surface 1101 of the blast gauge housing and adding replaceability support upon damage, but adding turbulence associated with the snap-in cover and one or more mechanical snap-in features to the blast gauge housing. The corners of the snap-in cover can be rounded or shaped into a ramp to help mitigate turbulence as much as possible. The snap-in cover can further be used with one or more other flat mesh sensor cover configurations illustrated herein.

In an example, the one or more mechanical snap-in features can include respective pairs of cantilever or torsion snap fits 1115-1118 and joining partners 1114, 1115 configured to hold the snap-in cover at the exterior surface 1101 of the blast gauge housing. In other examples, one or more other mechanical snap-in or other features can aid in location, such as pin and receptor, annular snap joints, etc.

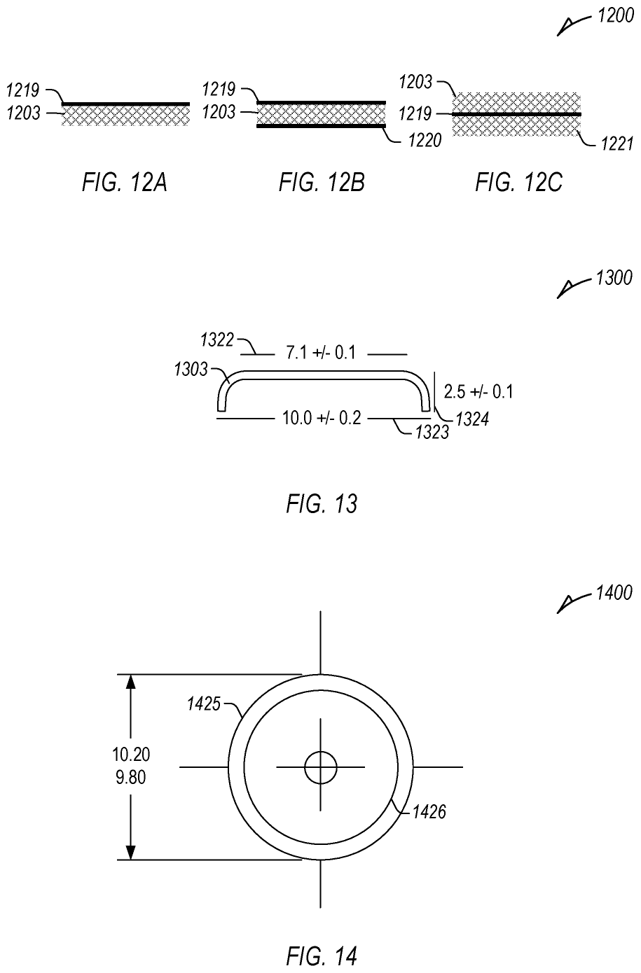

FIGS. 12A-12C illustrate different mesh configurations including two or three layers of coupled mesh (e.g., sintered, etc.) having one or more different material diameters (e.g., wire diameter, etc.) or opening parameters. FIG. 12A illustrates a first mesh configuration having two layers, a top mesh layer 1219 having openings with a first diameter (e.g., 0.0016 inches in diameter, etc.) (“fine mesh”) and a bottom layer mesh 1203 having openings with a second, larger diameter (e.g., 0.016 inches, etc.) (“coarse mesh”). In other examples, the layers can be reversed, and the top layer can have openings with the second diameter and the bottom layer can have openings with the first, smaller diameter. In an example, the coarse mesh can have a larger wire diameter and larger diameter openings, providing strength and minimizing airflow restriction.

FIGS. 12B and 12C illustrate second and third mesh configurations having three layers. The second mesh configuration has top and bottom mesh layers 1219, 1220 having openings with a first diameter (e.g., 0.0016 inches in diameter) (“fine mesh”) on either side of a middle layer 1203 having openings with a second, larger diameter (e.g., 0.016 inches, etc.) (“coarse mesh”). The first mesh configuration in FIG. 12A is thinner, having only two layers, but still provides protection to the sensing element. The second mesh configuration in FIG. 12B has smaller diameter openings at the top and bottom layers 1219, 1220, providing better debris resistance than the other illustrated configurations, but the openings having the smaller diameter top layer may tear easier than the corresponding layers having openings with the larger diameters, resulting in additional debris collection. The third mesh configuration in FIG. 12C may be more formable and rigid, having two layers with openings having larger diameters (“coarse mesh”) 1203, 1221, providing more puncture protection but less debris resistance than the second mesh configuration in FIG. 12B.

In certain examples, the mesh described herein can be made of a metal, such as a woven wire mesh, a stainless steel mesh, a nickel alloy wire mesh, etc., having different wire diameters or material thickness or diameter. In other examples, the mesh can be made of one or more other materials, such as PTFE, Teflon, Gore vent, etc.

FIGS. 13-14 illustrate example dimensions (in millimeters) 1300, 1400 of a flat mesh sensor cover 1303 (similar to that illustrated in FIGS. 4A and 4B). For example, FIG. 13 illustrates a cross section view of the flat mesh sensor cover 1303 with a first top diameter 1322 (e.g., 7.1+/−0.1 mm), a second outer diameter 1323 (e.g., 10.0+/−0.2 mm), and a height 1324 (e.g., 2.5+/−0.1 mm). Although illustrated as having such dimensions, in other examples, other dimensions can be used in various configurations. FIG. 14 illustrates a top view of the flat mesh sensor cover 1303 with a first top diameter 1426 and a second outer diameter 1425 (e.g., 9.80-10.2 mm, etc.).

FIG. 15 illustrates a cross section of an example fifth blast gauge 1500

with a flat mesh sensor cover 1503 (similar to that illustrated in FIG. 2) of mesh material at an exterior surface 1508 of a top portion 1502 of the fifth blast gauge 1500. The flat mesh sensor cover 1503 covers a sensing element 1528 coupled to a PC board 1530, with an interior thermoplastic 1529 covering the interior electronics of the fifth blast gauge 1500, offering additional water protection should the flat mesh sensor cover 1503 fail or become damaged. In certain examples, the sensing element 1528 can include a pressure sensor having an open port to receive impulse noise or shockwave events. Although the interior thermoplastic 1529 can cover various electronic components in the fifth blast gauge 1500, in certain examples, the port of the sensing element 1528 cannot be covered by the interior thermoplastic 1529 or any dense material without impacting sensor performance.

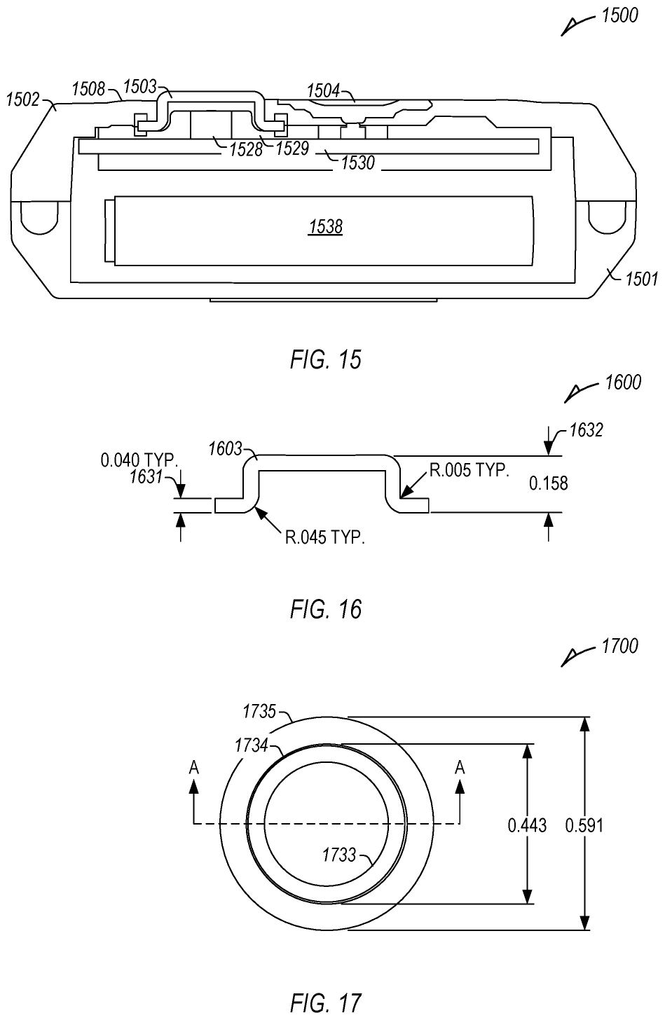

FIG. 16-17 illustrate example dimensions (in inches) 1600, 1700 of a flat mesh sensor cover 1603 (similar to that illustrated in FIG. 15). For example, FIG. 16 illustrates a cross section view of the flat mesh sensor cover 1603 having a mesh thickness 1631 (e.g., 0.040 inches) and a height 1632 (e.g., 0.158 inches). Although illustrated as having such dimensions, in other examples, other dimensions can be used in various configurations. FIG. 17 illustrates a top view of the flat mesh sensor cover 1603 with a first top diameter 1733, a second top diameter 1734 (e.g., 0.443 inches), and a third lower outer diameter 1735 (e.g., 0.591 inches).

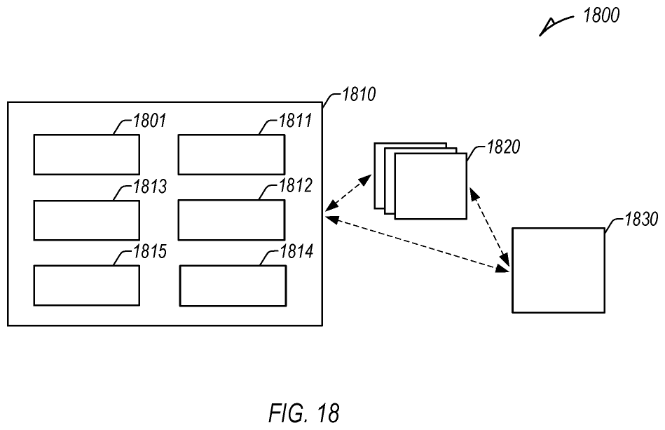

FIG. 18 illustrates an example system 1800 including a dosimeter 1810. The dosimeter 1810 can include a blast sensor 1801, such as one or more of the previous blast sensors or pressure sensors disclosed and described herein and additional components configured to enable the blast sensor 1801 to operate as a networked or stand-alone dosimeter device. The dosimeter 1810 can include a dosimeter circuit 1811 (or one or more other processors or control circuits) configured to receive information from the blast sensor 1801 (e.g., a pressure sensor, etc.) and to measure or monitor exposure to time-aggregate impulse noise or shock wave events, determine the magnitude of and count individual events, etc. The dosimeter 1810 can include a telemetry circuit 1812 configured to provide communication (wired or wireless) into or out of the dosimeter 1810 according to one or more communication protocols. In certain examples, the telemetry circuit 1812 can be configured for one or both of wired and wireless communication, in certain examples, separately selectable by a user, etc.

In an example, the dosimeter 1810 can include a housing (e.g., a wearable housing configured to be worn by a user, a non-wearable housing configured to be fixed to a specific location, etc.) configured to house the blast sensor 1801, the dosimeter circuit 1811, the telemetry circuit 1812, and a power source 1813 configured to provide power to the system 1800. In certain examples, the dosimeter 1810 can include one or more audible or visual indicators 1814 configured to provide one or more indications to a user (e.g., lights, speakers, a display screen, etc.), and one or more inputs 1815 (e.g., button interfaces, a touch-screen interface, etc.) configured to receive user input, commands, etc. In certain examples, the dosimeter 1810 can include one or more elastic cords or other physical attachments to enable secure attachment to the body or one or more other pieces of equipment, etc.

In an example, the power source 1813 can include a rechargeable battery. In other examples, the power source 1813 can specifically include a non-rechargeable battery configured to provide power for the components of the dosimeter 1810 for a substantial time period, such as up to 1-year or more, and the remaining components of the dosimeter 1810 can be configured for such long-term use (e.g., wired telemetry, etc.). In an example, the power source 1813 can be a replaceable battery, rechargeable or non-rechargeable.

In an example, the dosimeter circuit 1811 can include an ADC, or one or more amplifiers, pre-amplifiers, filter circuits, etc., configured to process an attenuated output signal from the blast sensor 1801. The dosimeter circuit 1811 can be configured to detect and record event information, such as impulse noise or shock wave event signatures in real time. The dosimeter circuit 1811 can be configured to distinguish between shock wave (e.g., blast overpressure (BOP)) and other impulse events, such as by using a detected rise time, frequency, event signature, etc., and separately account for such event types, and distinguish separate harms to the user, including between NIHL and TBI, etc. In addition, the dosimeter circuit 1811 can be configured to identify and reject mechanical impulse or mechanical shock events, such as due to motion or physical touching or contact of the dosimeter 1810, separate from an impulse noise or shock wave events, using signal characteristics, such as rise time, frequency, event signature, etc.

In addition, the dosimeter circuit 1811 can be configured to measure or determine exposure to adverse impulse noise or shock wave events over various time periods, such as over a 24-hour period, an 8-hour period, or longer or shorter time periods, to avoid deleterious effects to a user exposed to such adverse events. In an example, using information from the dosimeter circuit 1811 or information received from one or more other control circuits or processors, such as through the telemetry circuit 1812, the one or more audible or visual indicators 1814 can be configured to alert a user that one more harmful exposure levels is approaching or has been exceeded. In other examples, the one or more audible or visual indicators 1814 can notify a user that no harmful events or levels have been detected or exceeded.

In certain examples, the dosimeter 1810 can include one or more location sensors, such as GPS, cellular, or other location-based sensors. The dosimeter 1810 can further include one or more other atmospheric or environmental sensors (e.g., temperature, atmospheric pressure, etc.). In certain examples, the dosimeter circuit 1811 can be configured to adjust the measurement or monitoring of impulse noise or shock wave events or exposure using the received atmospheric or environmental information. In certain examples, the dosimeter circuit 1811 can include a clock and can be configured to store a log of timestamped events, such as having SPLs above a certain level, specific signatures, etc.

In an example, the system 1800 can include one or more additional dosimeters 1820, including one or more components illustrated in the dosimeter 1810, additional sensors, etc., or one or more additional stationary housings, sensors, or sensor systems. The system 1800 can further include a central processing device 1830 including one or more circuits or processors configured to provide information to or receive information from one or multiple sensors, such as one or more sensors associated with a single user, sensors associated with multiple users, one or more stationary sensors, or combinations thereof. The central processing device 1830 can store information from the dosimeter 1810 or the one or more additional dosimeters 1820 or stationary housings, sensors, or sensor systems. In an example, the central processing device 1830 can include a portable or non-portable computer hub, such as a tablet or a personal computer, configured to collect data from one or more sensors, dosimeters, etc., and store information for analysis, such as with respect to one or more sensors, dosimeters, users, groups of users, geographic area, etc., in a database.

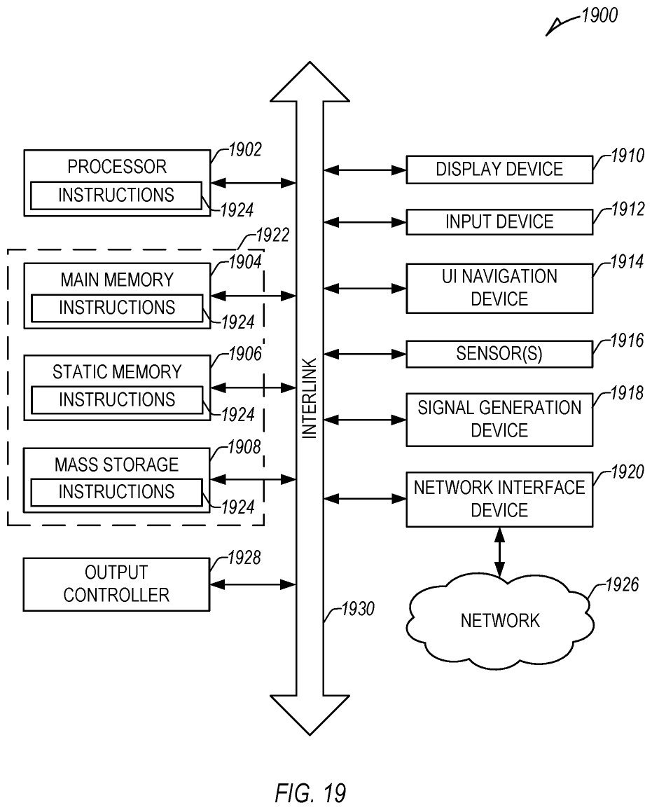

FIG. 19 illustrates a block diagram of an example machine 1900 upon which any one or more of the techniques (e.g., methodologies) discussed herein may perform. Portions of this description may apply to the computing framework of one or more of the dosimeters, circuits, or processors described herein. Examples, as described herein, may include, or may operate by, logic or a number of components, or mechanisms in the machine 1900. Circuitry (e.g., processing circuitry, a dosimeter circuit, etc.) is a collection of circuits implemented in tangible entities of the machine 1900 that include hardware (e.g., simple circuits, gates, logic, etc.). Circuitry membership may be flexible over time. Circuitries include members that may, alone or in combination, perform specified operations when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a machine-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable embedded hardware (e.g., the execution units or a loading mechanism) to create members of the circuitry in hardware via the variable connections to carry out portions of the specific operation when in operation. Accordingly, in an example, the machine-readable medium elements are part of the circuitry or are communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time. Additional examples of these components with respect to the machine 1900 follow.

In alternative embodiments, the machine 1900 may operate as a standalone device or may be connected (e.g., networked) to other machines. In a networked deployment, the machine 1900 may operate in the capacity of a server machine, a client machine, or both in server-client network environments. In an example, the machine 1900 may act as a peer machine in peer-to-peer (P2P) (or other distributed) network environment. The machine 1900 may be a personal computer (PC), a tablet PC, a set-top box (STB), a personal digital assistant (PDA), a mobile telephone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

The machine (e.g., computer system) 1900 may include a hardware processor 1902 (e.g., a central processing unit (CPU), a graphics processing unit (GPU), a hardware processor core, or any combination thereof), a main memory 1904, a static memory (e.g., memory or storage for firmware, microcode, a basic-input-output (BIOS), unified extensible firmware interface (UEFI), etc.) 1906, and mass storage 1908 (e.g., hard drive, tape drive, flash storage, or other block devices) some or all of which may communicate with each other via an interlink (e.g., bus) 1930. The machine 1900 may further include a display unit 1910, an alphanumeric input device 1912 (e.g., a keyboard), and a user interface (UI) navigation device 1914 (e.g., a mouse). In an example, the display unit 1910, input device 1912, and UI navigation device 1914 may be a touch screen display. The machine 1900 may additionally include a signal generation device 1918 (e.g., a speaker), a network interface device 1920, and one or more sensors 1916, such as a global positioning system (GPS) sensor, compass, accelerometer, or one or more other sensors. The machine 1900 may include an output controller 1928, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

Registers of the processor 1902, the main memory 1904, the static memory 1906, or the mass storage 1908 may be, or include, a machine-readable medium 1922 on which is stored one or more sets of data structures or instructions 1924 (e.g., software) embodying or utilized by any one or more of the techniques or functions described herein. The instructions 1924 may also reside, completely or at least partially, within any of registers of the processor 1902, the main memory 1904, the static memory 1906, or the mass storage 1908 during execution thereof by the machine 1900. In an example, one or any combination of the hardware processor 1902, the main memory 1904, the static memory 1906, or the mass storage 1908 may constitute the machine-readable medium 1922. While the machine-readable medium 1922 is illustrated as a single medium, the term “machine-readable medium” may include a single medium or multiple media (e.g., a centralized or distributed database, and/or associated caches and servers) configured to store the one or more instructions 1924.

The term “machine-readable medium” may include any medium that is capable of storing, encoding, or carrying instructions for execution by the machine 1900 and that cause the machine 1900 to perform any one or more of the techniques of the present disclosure, or that is capable of storing, encoding, or carrying data structures used by or associated with such instructions. Non-limiting machine-readable medium examples may include solid-state memories, optical media, magnetic media, and signals (e.g., radio frequency signals, other photon-based signals, sound signals, etc.). In an example, a non-transitory machine-readable medium comprises a machine-readable medium with a plurality of particles having invariant (e.g., rest) mass, and thus are compositions of matter. Accordingly, non-transitory machine-readable media are machine-readable media that do not include transitory propagating signals. Specific examples of non-transitory machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The instructions 1924 may be further transmitted or received over a communications network 1926 using a transmission medium via the network interface device 1920 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, the network interface device 1920 may include one or more physical jacks (e.g., Ethernet, coaxial, or phone jacks) or one or more antennas to connect to the communications network 1926. In an example, the network interface device 1920 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the machine 1900, and includes digital or analog communications signals or other intangible medium to facilitate communication of such software. A transmission medium is a machine-readable medium.

Various embodiments are illustrated in the figures above. One or more features from one or more of these embodiments may be combined to form other embodiments. Method examples described herein can be machine or computer-implemented at least in part. Some examples may include a computer-readable medium or machine-readable medium encoded with instructions operable to configure an electronic device or system to perform methods as described in the above examples. An implementation of such methods can include code, such as microcode, assembly language code, a higher-level language code, or the like. Such code can include computer readable instructions for performing various methods. The code can form portions of computer program products. Further, the code can be tangibly stored on one or more volatile or non-volatile computer-readable media during execution or at other times.

An example (e.g., “Example 1”) of subject matter (e.g., a blast sensor system) may comprise a housing having an opening; a blast sensor proximate an exterior surface of the housing configured to detect or monitor impulse noise or shock wave events at the exterior surface of the housing; and a flat mesh sensor cover coupled to the housing having a top surface that, when coupled to the housing, extends above the exterior surface of the housing less than a radius of the opening of the housing.

In Example 2, the subject matter of Example 1 may optionally be configured such that the top surface of the flat mesh sensor cover, when coupled to the housing, extends above the exterior surface of the housing less than one half of the radius of the opening of the housing.

In Example 3, the subject matter of Example 2 may optionally be configured such that the top surface of the flat mesh sensor cover, when coupled to the housing, extends above the exterior surface of the housing less than 2 mm.

In Example 4, the subject matter of any one or more of Examples 2-3 may optionally be configured such that the top surface of the flat mesh sensor cover, when coupled to the housing, extends above the exterior surface of the housing less than 1 mm.

In Example 5, the subject matter of any one or more of Examples 2-4 may optionally be configured such that the top surface of the flat mesh sensor cover, when coupled to the housing, does not extend above the exterior surface of the housing.

In Example 6, the subject matter of any one or more of Examples 2-5 may optionally be configured such that the top surface of the flat mesh sensor cover, when coupled to the housing, is substantially parallel to the exterior surface of the housing.

In Example 7, the subject matter of any one or more of Examples 2-6 may optionally be configured such that the top surface of the flat mesh sensor cover, when coupled to the housing, extends above the exterior surface of the housing less than one half of the radius of the opening of the housing to reduce dirt and debris collection over the blast sensor, reduce protruding edges and overall blast sensor system profile, and to reduce damage to the flat mesh sensor cover.

In Example 8, the subject matter of any one or more of Examples 1-7 may optionally be configured such that the flat mesh sensor cover is adhered to the exterior surface of the housing.

In Example 9, the subject matter of any one or more of Examples 1-8 may optionally be configured such that the flat mesh sensor cover is adhered to an inner surface of the housing.

In Example 10, the subject matter of any one or more of Examples 1-9 may optionally be configured such that the flat mesh sensor cover comprises sintered layers of different mesh material including a first layer having openings with a first diameter and a second layer having openings with a second diameter different than the first diameter.

An example (e.g., “Example 11”) of subject matter (e.g., a method) may comprise detecting or monitoring impulse noise or shock wave events at an exterior surface of a housing using a blast sensor proximate an opening in the housing through a flat mesh sensor cover coupled to the housing, wherein a top surface of the flat mesh sensor cover, when coupled to the housing, extends above the exterior surface of the housing less than a radius of the opening in the housing.

In Example 12, the subject matter of Example 11 may optionally be configured such that the top surface of the flat mesh sensor cover, when coupled to the housing, extends above the exterior surface of the housing less than one half of the radius of the opening of the housing.

In Example 13, the subject matter of Example 12 may optionally be configured such that the top surface of the flat mesh sensor cover, when coupled to the housing, extends above the exterior surface of the housing less than 2 mm.

In Example 14, the subject matter of any one or more of Examples 12-13 may optionally be configured such that the top surface of the flat mesh sensor cover, when coupled to the housing, extends above the exterior surface of the housing less than 1 mm.

In Example 15, the subject matter of any one or more of Examples 12-14 may optionally be configured such that the top surface of the flat mesh sensor cover, when coupled to the housing, does not extend above the exterior surface of the housing.

In Example 16, the subject matter of any one or more of Examples 12-15 may optionally be configured such that the top surface of the flat mesh sensor cover, when coupled to the housing, is substantially parallel to the exterior surface of the housing.

In Example 17, the subject matter of any one or more of Examples 12-16 may optionally be configured such that the top surface of the flat mesh sensor cover, when coupled to the housing, extends above the exterior surface of the housing less than one half of the radius of the opening of the housing to reduce dirt and debris collection over the blast sensor, reduce protruding edges and overall blast sensor system profile, and to reduce damage to the flat mesh sensor cover.

In Example 18, the subject matter of any one or more of Examples 11-17 may optionally be configured such that the flat mesh sensor cover is adhered to the exterior surface of the housing.

In Example 19, the subject matter of any one or more of Examples 11-18 may optionally be configured such that the flat mesh sensor cover is adhered to an inner surface of the housing.

In Example 20, the subject matter of any one or more of Examples 11-19 may optionally be configured such that the flat mesh sensor cover comprises sintered layers of different mesh material including a first layer having openings with a first diameter and a second layer having openings with a second diameter different than the first diameter.

In Example 21, subject matter (e.g., a system or apparatus) may optionally combine any portion or combination of any portion of any one or more of Examples 1-20 to comprise “means for” performing any portion of any one or more of the functions or methods of Examples 1-20.

The above detailed description is intended to be illustrative, and not restrictive. The scope of the disclosure should, therefore, be determined with references to the appended claims, along with the full scope of equivalents to which such claims are entitled.

What is claimed is:

1. A blast sensor system, comprising:
a housing having an opening;
a blast sensor proximate an exterior surface of the housing configured to detect or monitor impulse noise or shock wave events at the exterior surface of the housing; and
a flat mesh sensor cover coupled to the housing having a top surface that, when coupled to the housing, extends above the exterior surface of the housing less than a radius of the opening of the housing.

2. The blast sensor system of claim 1, wherein the top surface of the flat mesh sensor cover, when coupled to the housing, extends above the exterior surface of the housing less than one half of the radius of the opening of the housing.

3. The blast sensor system of claim 2, wherein the top surface of the flat mesh sensor cover, when coupled to the housing, extends above the exterior surface of the housing less than 2 mm.

4. The blast sensor system of claim 2, wherein the top surface of the flat mesh sensor cover, when coupled to the housing, extends above the exterior surface of the housing less than 1 mm.

5. The blast sensor system of claim 2, wherein the top surface of the flat mesh sensor cover, when coupled to the housing, does not extend above the exterior surface of the housing.

6. The blast sensor system of claim 2, wherein the top surface of the flat mesh sensor cover, when coupled to the housing, is substantially parallel to the exterior surface of the housing.

7. The blast sensor system of claim 2, wherein the top surface of the flat mesh sensor cover, when coupled to the housing, extends above the exterior surface of the housing less than one half of the radius of the opening of the housing to reduce dirt and debris collection over the blast sensor, reduce protruding edges and overall blast sensor system profile, and to reduce damage to the flat mesh sensor cover.

8. The blast sensor system of claim 1, wherein the flat mesh sensor cover is adhered to the exterior surface of the housing.

9. The blast sensor system of claim 1, wherein the flat mesh sensor cover is adhered to an inner surface of the housing.

10. The blast sensor system of claim 1, wherein the flat mesh sensor cover comprises sintered layers of different mesh material including a first layer having openings with a first diameter and a second layer having openings with a second diameter different than the first diameter.

11. A method comprising:
detecting or monitoring impulse noise or shock wave events at an exterior surface of a housing using a blast sensor proximate an opening in the housing through a flat mesh sensor cover coupled to the housing,
wherein a top surface of the flat mesh sensor cover, when coupled to the housing, extends above the exterior surface of the housing less than a radius of the opening in the housing.

12. The method of claim 11, wherein the top surface of the flat mesh sensor cover, when coupled to the housing, extends above the exterior surface of the housing less than one half of the radius of the opening of the housing.

13. The method of claim 12, wherein the top surface of the flat mesh sensor cover, when coupled to the housing, extends above the exterior surface of the housing less than 2 mm.

14. The method of claim 12, wherein the top surface of the flat mesh sensor cover, when coupled to the housing, extends above the exterior surface of the housing less than 1 mm.

15. The method of claim 12, wherein the top surface of the flat mesh sensor cover, when coupled to the housing, does not extend above the exterior surface of the housing.

16. The method of claim 12, wherein the top surface of the flat mesh sensor cover, when coupled to the housing, is substantially parallel to the exterior surface of the housing.

17. The method of claim 12, wherein the top surface of the flat mesh sensor cover, when coupled to the housing, extends above the exterior surface of the housing less than one half of the radius of the opening of the housing to reduce dirt and debris collection over the blast sensor, reduce protruding edges and overall blast sensor system profile, and to reduce damage to the flat mesh sensor cover.

18. The method of claim 11, wherein the flat mesh sensor cover is adhered to the exterior surface of the housing.

19. The method of claim 11, wherein the flat mesh sensor cover is adhered to an inner surface of the housing.

20. The method of claim 11, wherein the flat mesh sensor cover comprises sintered layers of different mesh material including a first layer having openings with a first diameter and a second layer having openings with a second diameter different than the first diameter.
